(19) United States
(12) Patent Application Publication
(10) Pub. No.: US 2026/0362732 A1
(43) Pub. Date: Nov. 12, 2026

(54) SEMICONDUCTOR DEVICE, SEMICONDUCTOR DEVICE MANUFACTURING METHOD, AND ELECTRONIC DEVICE

(71) Applicant: Fujitsu Limited, Kawasaki-shi (JP)

(72) Inventor: Atsushi YAMADA, Hiratsuka (JP)

(73) Assignee: Fujitsu Limited, Kawasaki-shi (JP)

(21) Appl. No.: 19/659,855

(22) Filed: Apr. 27, 2026

(30) Foreign Application Priority Data
May 9, 2025 (JP) 2025-078580

(51) Int. Cl. H10D 30/47; H10D 30/01; H10D 62/60; H10D 62/824; H10D 64/27; H10D 62/10

(52) U.S. Cl. CPC H10D 30/475; H10D 30/015; H10D 62/60; H10D 62/824; H10D 64/411; H10D 62/102

(57) ABSTRACT

A semiconductor device includes a substrate, a channel layer, and a barrier layer. The substrate contains AlN. The channel layer is formed at a side of the substrate where a first surface of the substrate is located, and contains AlGaN. The barrier layer is formed at a side of the channel layer where a second surface of the channel layer opposite to the substrate is located. The channel layer and the barrier layer are lattice-matched to the substrate. The channel layer has an Al composition that increases in a direction from the substrate side toward a barrier layer side.

### CROSS-REFERENCE TO RELATED APPLICATION

This application is based upon and claims the benefit of priority of the prior Japanese Patent Application No. 2025-078580, filed on May 9, 2025, the entire contents of which are incorporated herein by reference.

### FIELD

The embodiments discussed herein relate to a semiconductor device, a semiconductor device manufacturing method, and an electronic device.

### BACKGROUND

There is known a semiconductor device including a buffer layer made of a nitride semiconductor formed on a semiconductor substrate and a channel layer made of a nitride semiconductor formed over the buffer layer, the channel layer being made of AlₓGa₁₋ₓN (0 < X < 1). See, for example, Japanese Laid-open Patent Application No. 2001-326232.

### SUMMARY

In one aspect, there is provided a semiconductor device including: a substrate containing aluminum nitride (AlN); a channel layer formed at a side of the substrate where a first surface of the substrate is located, the channel layer containing aluminum gallium nitride (AlGaN); and a barrier layer formed at a side of the channel layer where a second surface of the channel layer opposite to the substrate is located, wherein the channel layer and the barrier layer are lattice-matched to the substrate, and the channel layer has an Al composition that increases in a direction from the substrate toward the barrier layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of a semiconductor device;

FIGS. 2A and 2B illustrate an energy band structure and an electron concentration distribution of the example of a semiconductor device;

FIG. 3 illustrates an example of a semiconductor device according to a first embodiment;

FIGS. 4A to 4C illustrate the relationship between the Al composition and spontaneous polarization of a nitride semiconductor;

FIGS. 5A and 5B illustrate an energy band structure and an electron concentration distribution of the example of the semiconductor device according to the first embodiment;

FIG. 6 illustrates an example of a characteristic of AlGaN;

FIG. 7 illustrates an example of a semiconductor device according to a second embodiment;

FIGS. 8A and 8B illustrate an example of a method for manufacturing a semiconductor device according to a third embodiment (part 1);

FIGS. 9A and 9B illustrate the example of the method for manufacturing the semiconductor device according to the third embodiment (part 2);

FIG. 10 illustrates an example of a semiconductor package according to a fourth embodiment;

FIG. 11 illustrates an example of a power factor correction circuit according to a fifth embodiment;

FIG. 12 illustrates an example of a power supply device according to a sixth embodiment; and

FIG. 13 illustrates an example of an amplifier according to a seventh embodiment.

### DESCRIPTION OF EMBODIMENTS

In a semiconductor device including a high electron mobility transistor (HEMT), AlGaN may be used for a channel layer. However, with conventional semiconductor devices using AlGaN for a channel layer, a high-performance semiconductor device having excellent output characteristics is not obtained in some cases.

First, an example of a semiconductor device will be described.

A semiconductor device using a nitride semiconductor has been developed as a high breakdown voltage and high output device by utilizing characteristics such as a high saturation electron velocity and a wide band gap. As a semiconductor device using a nitride semiconductor, a field effect transistor (FET), for example, a HEMT has been largely reported. As one of HEMTs, an HEMT using aluminum gallium nitride (AlGaN) as a barrier layer and gallium nitride (GaN) as a channel layer is known. In this HEMT, a high concentration of two-dimensional electron gas (2DEG) is generated in GaN of the channel layer by spontaneous polarization of AlGaN of the barrier layer and piezoelectric polarization generated in AlGaN of the barrier layer due to strain caused by a lattice constant difference between AlGaN of the barrier layer and GaN of the channel layer. As a result, a high output device is realized.

In addition, with respect to a semiconductor device using a nitride semiconductor, a semiconductor device using AlGaN, which is an ultra-wide band gap material, for a channel layer of an HEMT has been proposed in order to further improve performance.

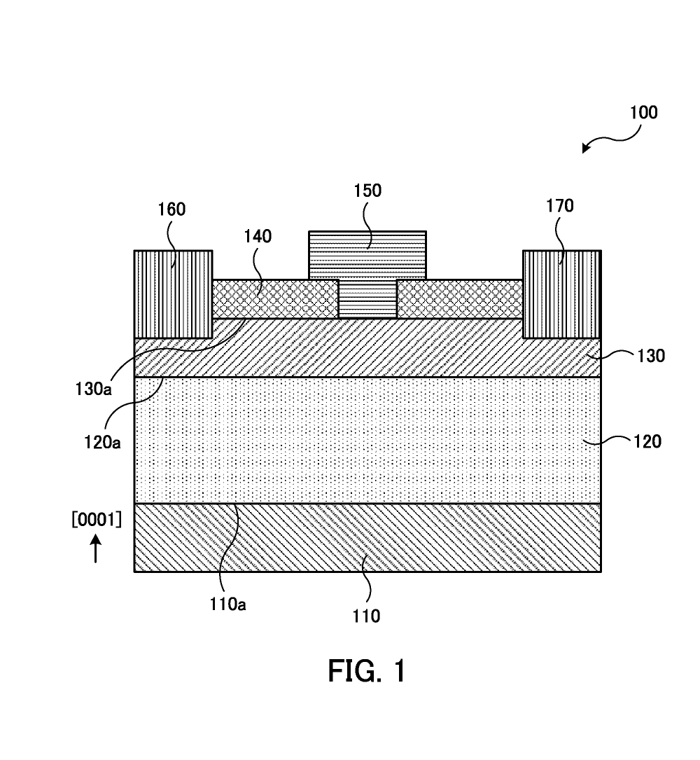

FIG. 1 illustrates an example of a semiconductor device. FIG. 1 is a fragmentary schematic sectional view of an example of a semiconductor device.

A semiconductor device 100 illustrated in FIG. 1 is an example of a HEMT using a nitride semiconductor. The semiconductor device 100 includes a substrate 110, a channel layer 120, a barrier layer 130, a passivation film 140, a gate electrode 150, a source electrode 160, and a drain electrode 170.

For example, aluminum nitride (AlN) is used for the substrate 110. One surface 110a of the substrate 110 is a group III polar plane, that is to say, a (0001) plane. The channel layer 120 is formed at a side of the substrate 110 where the surface 110a of the substrate 110 is located.

For example, AlGaN having a constant Al composition is used for the channel layer 120. A surface 120a of the channel layer 120 opposite to the substrate 110 is a group III polar plane, that is to say, a (0001) plane. The barrier layer 130 is formed at a side of the channel layer 120 where the surface 120a of the channel layer 120 is located.

For example, AlN is used for the barrier layer 130. A surface 130a of the barrier layer 130 opposite to the channel layer 120 is a group III polar plane, that is to say, a (0001) plane. The gate electrode 150, the source electrode 160, the drain electrode 170, and the passivation film 140 are formed at a side of the barrier layer 130 where the surface 130a of the barrier layer 130 is located.

The source electrode 160 and the drain electrode 170 are separated from each other. The gate electrode 150 is formed between the source electrode 160 and the drain electrode 170 so as to be separated therefrom. Predetermined metal is used for the gate electrode 150, the source electrode 160, and the drain electrode 170.

The passivation film 140 is formed between the gate electrode 150 and the source electrode 160 and between the gate electrode 150 and the drain electrode 170. An insulating film, such as SiN, is used for the passivation film 140.

With the semiconductor device 100, a 2DEG region is generated in the channel layer 120 by spontaneous polarization of AlN of the barrier layer 130 and piezoelectric polarization generated in AlN of the barrier layer 130 due to strain caused by a lattice constant difference between AlGaN of the channel layer 120 and AlN of the barrier layer 130.

At the time of the operation of the semiconductor device 100, for example, a voltage is applied so that the drain electrode 170 has a higher potential than the source electrode 160, and a predetermined voltage is applied to the gate electrode 150. The amount of charges in the 2DEG region of the channel layer 120 right under the gate electrode 150 is controlled by the field effect of the voltage applied to the gate electrode 150, and the magnitude of an output drain current flowing between the source electrode 160 and the drain electrode 170 is controlled. For example, the transistor function of the semiconductor device 100 is realized in this way.

As described above, the semiconductor device 100 using AlGaN for the channel layer 120 and AlN for the barrier layer 130 has a relatively small characteristic variation even at a high temperature. Therefore, the semiconductor device 100 is expected to operate stably in a higher temperature environment, compared with a semiconductor device using GaN for the channel layer 120 and AlGaN for the barrier layer 130.

In addition, with the semiconductor device 100, confinement of electrons is enhanced by a relatively large band offset between AlGaN of the channel layer 120 and AlN of the substrate 110 and the barrier layer 130. Therefore, the effect of suppressing the occurrence of a leakage current due to electron diffusion to a deep portion of the device is expected.

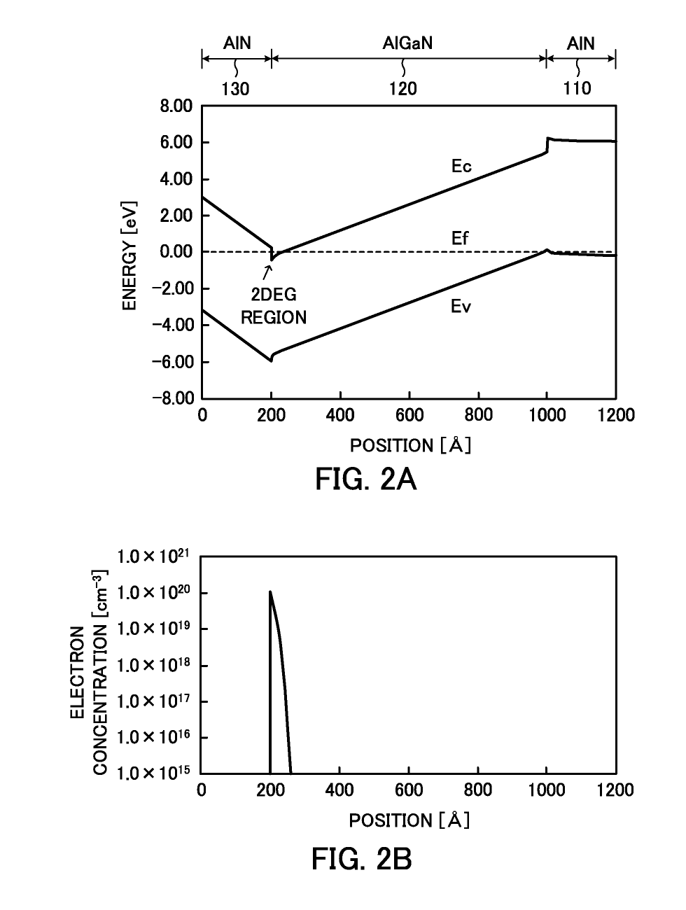

However, with the semiconductor device 100 adopting the above-described structure, electron concentration and electron mobility in the channel layer 120 using AlGaN may be relatively low. This point will be described with reference to FIGS. 2A and 2B.

FIGS. 2A and 2B illustrate an energy band structure and an electron concentration distribution of the example of a semiconductor device. FIG. 2A illustrates an energy band structure of the example of a semiconductor device. In FIG. 2A, Ec represents a conduction band, Ev represents a valence band, and Ef represents a Fermi level. FIG. 2B illustrates an electron concentration distribution of the example of a semiconductor device.

For example, with the semiconductor device 100 in which AlGaN having a constant Al composition is used for the channel layer 120 and AlN is used for the substrate 110 and the barrier layer 130 sandwiching the channel layer 120, an energy band structure is illustrated in FIG. 2A. The conduction band Ec of AlGaN of the channel layer 120 in the vicinity of AlN of the barrier layer 130 is on the lower energy side than the Fermi level Ef and the 2DEG region is generated in the channel layer 120 in the vicinity of the barrier layer 130.

With the semiconductor device 100, because AlGaN of the channel layer 120 is sandwiched between AlN of the substrate 110 and AlN of the barrier layer 130, a strong internal electric field is generated in the channel layer 120 due to a relatively large band offset therebetween. With the semiconductor device 100, the conduction band Ec of the channel layer 120 at the side of the substrate 110 is greatly raised due to the strong internal electric field, as illustrated in FIG. 2A. As a result, with the semiconductor device 100, as illustrated in FIG. 2B, an electron concentration distribution in the 2DEG region in the channel layer 120 is narrowed. Therefore, with the semiconductor device 100, it may be that electron concentration and electron mobility in the channel layer 120 is not sufficiently increased. If electron concentration or electron mobility in the channel layer 120 is not sufficient, then it may be that a high-performance semiconductor device 100 having excellent output characteristics is not obtained.

In view of the above points, a high-performance semiconductor device is realized by adopting a structure described below as an embodiment.

### First Embodiment

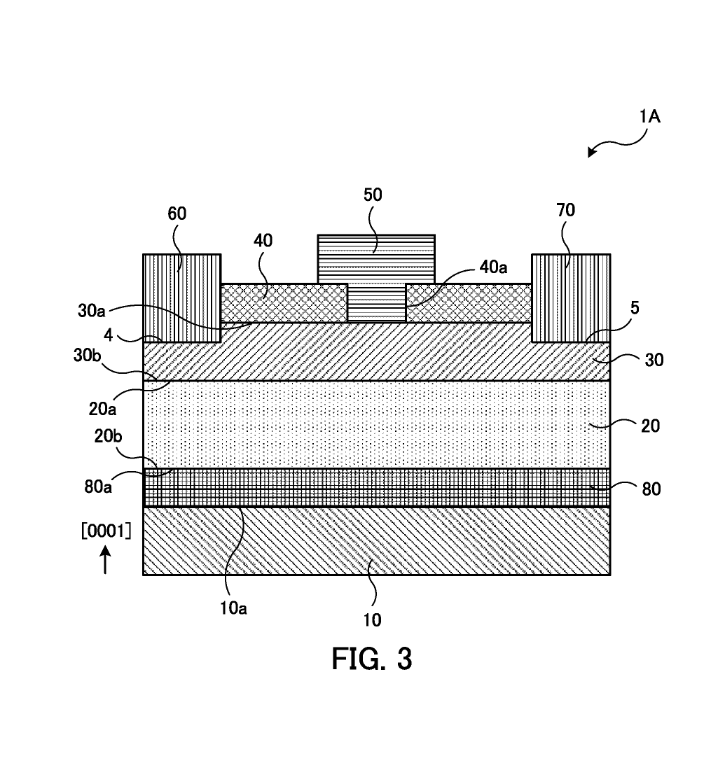

FIG. 3 illustrates an example of a semiconductor device according to a first embodiment. FIG. 3 is a fragmentary schematic sectional view of an example of a semiconductor device.

A semiconductor device 1A illustrated in FIG. 3 is an example of a HEMT using a nitride semiconductor. The semiconductor device 1A includes a substrate 10, a buffer layer 80, a channel layer 20, a barrier layer 30, a passivation film 40, a gate electrode 50, a source electrode 60, and a drain electrode 70. In the semiconductor device 1A, the channel layer 20 is also referred to as an “electron transit layer” and the barrier layer 30 is also referred to as an “electron supply layer”. In the semiconductor device 1A, a 2DEG region is generated in the channel layer 20 near the barrier layer 30.

For example, AlN is used for the substrate 10. The substrate 10 may be a single-layer substrate or a substrate having a laminated structure. As an example, a single-layer AlN substrate is used as the substrate 10. Alternatively, a substrate having a laminated structure including a base substrate and an AlN layer laminated thereon may be used as the substrate 10. If the substrate 10 having the laminated structure, various substrates such as silicon carbide (SiC), sapphire, zinc oxide (ZnO), GaN, silicon (Si), diamond, gallium oxide (Ga₂O₃), scandium aluminum magnesium oxide (ScAlMgO₄), or AlN may be used as the base substrate.

The substrate 10 has AlN on one surface 10a thereof. The AlN on the surface 10a of the substrate 10 is, for example, a part of a single-layer AlN substrate, or an AlN layer laminated on the base substrate or a part thereof. The surface 10a of the substrate 10 is a group III polar surface, that is to say, a (0001) plane. The surface 10a of the substrate 10 is also referred to as a “first surface”.

The buffer layer 80 is formed at a side of the substrate 10 where the surface 10a is located. For example, AlGaN is used for the buffer layer 80. For example, AlGaN having a constant Al composition is used for the buffer layer 80. Alternatively, a laminated structure of a plurality of AlGaNs having different Al compositions may be used for the buffer layer 80. A surface 80a of the buffer layer 80 opposite to the substrate 10 is a group III polar plane, that is, a (0001) plane.

The channel layer 20 is formed at a side of the buffer layer 80 where the surface 80a is located. For example, AlGaN is used for the channel layer 20. A surface 20a of the channel layer 20 opposite to the substrate 10 is a group III polar plane, that is to say, a (0001) plane. The barrier layer 30 is formed at a side of the channel layer 20 where the surface 20a is located. The surface 20a of the channel layer 20 opposite to the substrate 10 is also referred to as a “second surface”.

AlGaN in which the Al composition increases in a direction from the buffer layer 80 or the substrate 10 toward the barrier layer 30 is used as AlGaN of the channel layer 20. Hereinafter, AlGaN in which the Al composition increases in the direction from the buffer layer 80 or the substrate 10 toward the barrier layer 30 is also referred to as “gradient composition AlGaN”.

For example, AlGaN in which the difference between the average Al composition and the Al composition (= 1.0) of AlN of the substrate 10 is 0.5 or less is used as the gradient composition AlGaN of the channel layer 20. It may also be said that AlGaN having an average Al composition of 0.5 or more is used as the gradient composition AlGaN of the channel layer 20. Gradient composition AlGaN set to such an average Al composition is used for the channel layer 20. By doing so, properties of an n-type semiconductor described later are realized. As a result, electron concentration and electron mobility in the channel layer 20 are improved.

For example, the Al composition at the surface 20b of the gradient composition AlGaN of the channel layer 20, at a side where the buffer layer 80 is located, is preferably set to 0.3 or more, and more preferably set to 0.5 or more in order to improve the breakdown voltage of the semiconductor device 1A. For example, the Al composition at the surface 20a of the gradient composition AlGaN of the channel layer 20, at the side where the barrier layer 30 is located, is preferably set to 0.6 or more, and more preferably set to 0.7 or more in order to improve electron mobility in the channel layer 20 near the barrier layer 30 in the semiconductor device 1A.

For example, the amount of a change in the Al composition of the gradient composition AlGaN of the channel layer 20 that increases in a direction from the buffer layer 80 or the substrate 10 toward the barrier layer 30 is preferably set to 0.0002 nm⁻¹ or more, and more preferably set to 0.001 nm⁻¹ or more. In the semiconductor device 1A, gradient composition AlGaN set to such a change amount is used for the channel layer 20. By doing so, the properties of an n-type semiconductor described later are realized. As a result, electron concentration and electron mobility in the channel layer 20 are realized.

For example, the Al composition of the gradient composition AlGaN of the channel layer 20 may continuously increase in the direction from the buffer layer 80 or the substrate 10 toward the barrier layer 30. Alternatively, the Al composition of the gradient composition AlGaN of the channel layer 20 may increase stepwise in the direction from the buffer layer 80 or the substrate 10 toward the barrier layer 30.

For example, the average Al composition of the gradient composition AlGaN of the channel layer 20 is set to be higher than the Al composition or the average Al composition of AlGaN of the buffer layer 80. By doing so, the generation of two-dimensional hole gas (2DHG) in the channel layer 20 caused by the polarization of the buffer layer 80 is suppressed. Therefore, the disappearance of charges in the 2DEG region in the channel layer 20, a decrease in electron concentration, a decrease in electron mobility, and the like due to the generation of the 2DHG are suppressed.

The barrier layer 30 is formed at the side of the channel layer 20 where the surface 20a is located. In order to generate the 2DEG region in the channel layer 20 near the barrier layer 30, a nitride semiconductor having a band gap larger than that of the gradient composition AlGaN of the channel layer 20 is used for the barrier layer 30. A surface 30a of the barrier layer 30 opposite to the channel layer 20 is a group III polar plane, that is to say, a (0001) plane.

For the barrier layer 30, a nitride semiconductor containing Al (hereinafter, also referred to as an “Al-containing nitride semiconductor”) is used as a nitride semiconductor having a band gap larger than that of the gradient composition AlGaN of the channel layer 20. For example, AlN is used as an Al-containing nitride semiconductor of the barrier layer 30. In place of AlN, AlGaN having an Al composition higher than that of the gradient composition AlGaN of the channel layer 20 may be used for the barrier layer 30. For example, an Al-containing nitride semiconductor such as indium aluminum gallium nitride (InAlGaN) or indium aluminum nitride (InAlN) may be used for the barrier layer 30 as long as the barrier layer 30 has a band gap larger than that of the gradient composition AlGaN of the channel layer 20.

AlN, AlGaN, InAlGaN, and InAlN are each a type of Al-containing nitride semiconductor. For the barrier layer 30, for example, a single-layer Al-containing nitride semiconductor may be used or an Al-containing nitride semiconductor in which a plurality of layers are laminated may be used.

If an Al-containing nitride semiconductor is used for the barrier layer 30, the Al composition of the gradient composition AlGaN of the channel layer 20 and the Al composition of the Al-containing nitride semiconductor of the barrier layer 30 are adjusted so that the band gap of the barrier layer 30 is larger than that of the channel layer 20.

At this time, the Al composition at the surface 20a of the gradient composition AlGaN of the channel layer 20 is set to be lower than the Al composition at the surface 30b of the Al-containing nitride semiconductor of the barrier layer 30 at the side where the channel layer 20 is located. For example, the Al composition at the surface 20a of the channel layer 20 is set to be lower than the Al composition at the surface 30b of the barrier layer 30 by 0.1 or more. By setting the Al composition at the surface 20a of the channel layer 20 to be lower than the Al composition at the surface 30b of the barrier layer 30, a HEMT capable of generating a 2DEG region in which a constant electron concentration and electron mobility are obtained in the channel layer 20 is realized. The surface 30b of the barrier layer 30 facing toward the channel layer 20 is also referred to as a “third surface”.

The gate electrode 50, the source electrode 60, and the drain electrode 70 are formed at a side of the barrier layer 30 where the surface 30a is located. The surface 30a of the barrier layer 30 opposite to the channel layer 20 is also referred to as a “fourth surface”.

The source electrode 60 and the drain electrode 70 are separated from each other. For example, the source electrode 60 and the drain electrode 70 are formed in recesses 4 and 5, respectively, formed in the surface 30a of the barrier layer 30. Metal, such as tantalum (Ta) or aluminum (Al), is used for the source electrode 60 and the drain electrode 70. One or more metals may be used for the source electrode 60 and the drain electrode 70. The source electrode 60 and the drain electrode 70 are formed to function as an ohmic electrode.

A regrown layer formed using a nitride semiconductor containing n-type impurities (hereinafter, also referred to as an “n-type nitride semiconductor”) may be formed as a contact layer on portions of the barrier layer 30 corresponding to regions to which the source electrode 60 and the drain electrode 70 are connected or on portions of the barrier layer 30 and the channel layer 20 corresponding to regions to which the source electrode 60 and the drain electrode 70 are connected.

The gate electrode 50 is formed between the source electrode 60 and the drain electrode 70 so as to be separated therefrom. For example, the gate electrode 50 is formed in an opening 40a formed in the passivation film 40. Metal, such as nickel (Ni) or gold (Au), is used for the gate electrode 50. One or more metals may be used for the gate electrode 50. For example, the gate electrode 50 is formed to function as a Schottky electrode.

A cap layer (not illustrated) formed using a doped or non-doped nitride semiconductor may be interposed between the gate electrode 50 and the barrier layer 30. For example, a nitride semiconductor doped with p-type impurities (hereinafter, also referred to as a “p-type nitride semiconductor”) may be formed as a cap layer in order to modulate the amount of charges in the 2DEG region generated in the channel layer 20. Alternatively, in order to protect the channel layer 20, the barrier layer 30, and the like from the outside, a non-doped nitride semiconductor may be formed as a cap layer.

In addition, the gate electrode 50 may have a metal insulator semiconductor (MIS) gate structure in which a gate insulating film (not illustrated) formed using an oxide, a nitride, an oxynitride, or the like is interposed between the gate electrode 50 and the barrier layer 30.

The passivation film 40 is formed between the gate electrode 50 and the source electrode 60 and between the gate electrode 50 and the drain electrode 70, at the side of the barrier layer 30 where the surface 30a is located. For example, an oxide, a nitride, or an oxynitride containing at least one of Si, Al, hafnium (Hf), zirconium (Zr), titanium (Ti), Ta, and tungsten (W) is used for the passivation film 40. As an example, silicon nitride (SiN) is used for the passivation film 40.

In the semiconductor device 1A having the structure described above, the buffer layer 80, the channel layer 20, and the barrier layer 30 are grown at the side of the substrate 10 where the surface 10a is located by, for example, a metal organic chemical vapor deposition (MOCVD) or metal organic vapor phase epitaxy (MOVPE) method or a molecular beam epitaxy (MBE) method.

The lattice constant of the a-axis orthogonal to the c-axis ( direction) of AlGaN is relatively close to the lattice constant of the a-axis orthogonal to the c-axis of AlN. The lattice constant of the a-axis of AlGaN approaches the lattice constant of the a-axis of AlN as the Al composition increases. AlGaN grown on AlN using the MOVPE method or the like is relatively easily lattice-matched with the underlying AlN, and lattice mismatch with the underlying AlN is relatively unlikely to occur.

In the semiconductor device 1A, an Al-containing nitride semiconductor that is easily lattice-matched with AlN of the substrate 10 is used for each of the buffer layer 80, the channel layer 20, and the barrier layer 30.

In the semiconductor device 1A, for example, the Al composition of AlGaN of the buffer layer 80 is adjusted so that AlN of the substrate 10 and AlGaN of the buffer layer 80 grown thereon are lattice-matched. Furthermore, for example, the Al composition, the amount of a change in the Al composition, and the average Al composition of the gradient composition AlGaN of the channel layer 20 are adjusted so that AlGaN of the buffer layer 80 and the gradient composition AlGaN of the channel layer 20 grown thereon are lattice-matched. Moreover, for example, the Al composition of the Al-containing nitride semiconductor of the barrier layer 30 is adjusted so that the gradient composition AlGaN of the channel layer 20 and the Al-containing nitride semiconductor of the barrier layer 30 grown thereon are lattice-matched.

In addition to the Al composition, the thickness in the c-axis direction of each of the Al-containing nitride semiconductors used for the buffer layer 80, the channel layer 20, and the barrier layer 30 may be further adjusted in order to achieve lattice matching with AlN of the substrate 10.

In the semiconductor device 1A, the type, Al composition, and the like of each of the Al-containing nitride semiconductors used for the buffer layer 80, the channel layer 20, and the barrier layer 30 are adjusted and the buffer layer 80, the channel layer 20, and the barrier layer 30 are lattice-matched with the substrate 10. In the semiconductor device 1A, it may be said that the a-axis lattice constant of each of the Al-containing nitride semiconductors used for the buffer layer 80, the channel layer 20, and the barrier layer 30 is equal to the a-axis lattice constant of AlN used for the substrate 10, or is equal to the a-axis lattice constant of AlN used for the substrate 10 to the extent that lattice mismatch does not occur.

Whether the buffer layer 80, the channel layer 20, and the barrier layer 30 are lattice-matched with the substrate 10 is evaluated using, for example, an X-ray diffractometer.

AlN is used for the substrate 10 on which the buffer layer 80, the channel layer 20, and the barrier layer 30 are grown in a lattice-matched way. As the substrate 10, a single-layer AlN substrate or a substrate obtained by laminating an AlN layer on a base substrate is used.

If AlGaN of the buffer layer 80, a gradient composition AlGaN of the channel layer 20, and an Al-containing nitride semiconductor of the barrier layer 30 are grown on another substrate, for example, a SiC substrate, then the following may occur. That is to say, dislocations are likely to occur in the channel layer 20. The density of dislocation exceeds 1×10⁸ cm⁻², which may cause a decrease in electron concentration and electron mobility due to the dislocations. The decrease in electron concentration and electron mobility due to the dislocation causes degradation in the performance of the semiconductor device 1A.

In contrast, if the substrate 10 containing AlN described above is used, then the density of dislocations in the channel layer 20 is suppressed to 1×10⁸ cm⁻² or less. If the substrate 10 containing AlN having good crystal quality, then the density of dislocations in the channel layer 20 is further suppressed to 1×10⁶cm⁻² or less. By using the substrate 10 containing AlN and suppressing the density of dislocations in the channel layer 20 to 1×10⁸ cm⁻² or less, degradation of the performance of the semiconductor device 1A is suppressed.

Even if the substrate 10 containing AlN is used, it may be that the density of dislocations in the channel layer 20 is not suppressed to less than a certain value, for example, less than 1×10⁴ cm⁻², due to the crystal quality of the substrate 10 or the lamination growth process of Al-containing nitride semiconductors on the substrate 10. Even in this case, by using the substrate 10 containing AlN, the density of dislocations in the channel layer 20 is suppressed within a certain range, for example, within the range of 1×10⁴ cm⁻² or more and 1×10⁸ cm⁻² or less.

In addition, if the number of dislocations inside the channel layer 20 increases at the time of the growth of the channel layer 20, impurities, such as carbon or oxygen, are likely to be incorporated around the dislocations. If AlGaN of the buffer layer 80, a gradient composition AlGaN of the channel layer 20, and an Al-containing nitride semiconductor of the barrier layer 30 are grown on another substrate, for example, a SiC substrate, instead of the substrate 10 containing AlN, then the following may occur. That is to say, because dislocations are likely to occur in the channel layer 20, carbon or oxygen as impurities is likely to be incorporated into the channel layer 20. As a result, carbon concentration or oxygen concentration in the channel layer 20 exceeds 1×10¹⁹ cm⁻³, which may cause a decrease in electron mobility or the like. The decrease in electron mobility or the like due to the incorporation of carbon or oxygen causes deterioration in the performance of the semiconductor device 1A.

In contrast, if the substrate 10 containing AlN described above is used, then dislocations in the channel layer 20 are suppressed, carbon concentration in the channel layer 20 is suppressed to 1×10¹⁹ cm⁻³ or less, and oxygen concentration in the channel layer 20 is suppressed to 1×10¹⁹ cm⁻³ or less. If the substrate 10 containing AlN having good crystal quality, carbon concentration in the channel layer 20 is further suppressed to 1×10¹⁸ cm⁻³ or less, and oxygen concentration in the channel layer 20 is further suppressed to 1×10¹⁸ cm⁻³ or less. By using the substrate 10 containing AlN and suppressing carbon or oxygen concentration in the channel layer 20 to 1×10¹⁹ cm⁻³ or less, deterioration in the performance of the semiconductor device 1A is suppressed.

Even if the substrate 10 containing AlN is used, it may be that carbon concentration or oxygen concentration in the channel layer 20 is not suppressed to less than a certain value, for example, less than 1×10¹⁴ cm⁻³, due to the crystal quality of the substrate 10 or the lamination growth process of Al-containing nitride semiconductors on the substrate 10. Even in this case, by using the substrate 10 containing AlN, carbon concentration in the channel layer 20 is suppressed within a certain range, for example, within the range of 1×10¹⁴ cm⁻³ or more and 1×10¹⁹ cm⁻³ or less. Furthermore, by using the substrate 10 containing AlN, oxygen concentration in the channel layer 20 is suppressed within a certain range, for example, within the range of 1×10¹⁴ cm⁻³ or more and 1×10¹⁹ cm⁻³ or less.

With the semiconductor device 1A (FIG. 3) having the structure described above, a predetermined voltage is applied to each of the source electrode 60, the drain electrode 70, and the gate electrode 50, and operation as a transistor is realized. When the semiconductor device 1A operates, for example, a voltage is applied so that the drain electrode 70 has a higher potential than the source electrode 60, and a predetermined voltage is applied to the gate electrode 50. The amount of charges in the 2DEG region of the channel layer 20 right under the gate electrode 50 is controlled by the field effect of the voltage applied to the gate electrode 50, and the magnitude of an output drain current flowing between the source electrode 60 and the drain electrode 70 is controlled. For example, the transistor function of the semiconductor device 1A is realized in this way.

Next, the channel layer 20 using a gradient composition AlGaN will be described.

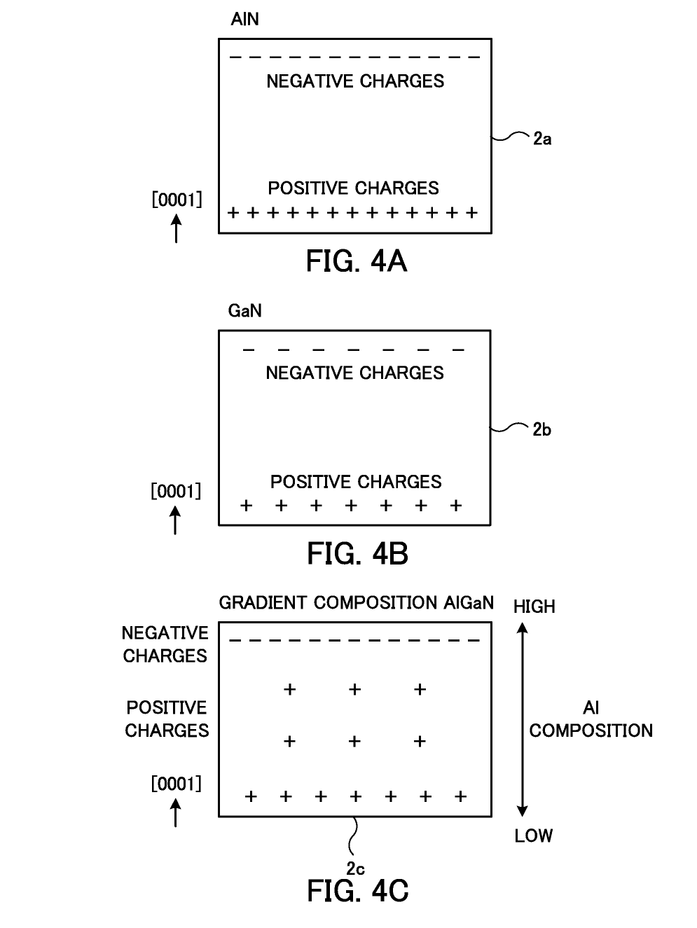

FIGS. 4A to 4C illustrate the relationship between the Al composition and spontaneous polarization of a nitride semiconductor. FIG. 4A schematically illustrates the state of spontaneous polarization of AlN. FIG. 4B schematically illustrates the state of spontaneous polarization of GaN. FIG. 4C schematically illustrates the state of spontaneous polarization of a gradient composition AlGaN.

A nitride semiconductor has spontaneous polarization in the direction (along the c-axis). AlN has a stronger spontaneous polarization than GaN. For example, as illustrated in FIGS. 4A and 4B, if the direction is defined as the upward direction, then negative charges (indicated by “-”) are generated on an upper end side of each of an AlN layer 2a and a GaN layer 2b and positive charges (indicated by “+”) are generated on an lower end side of each of the AlN layer 2a and the GaN layer 2b. Because AlN has stronger spontaneous polarization than GaN, the amount of charges generated in the AlN layer 2a is larger than the amount of charges generated in the GaN layer 2b.

AlGaN, which is mixed crystal, has an intermediate charge amount between that of AlN and that of GaN according to its Al composition. In the case of the gradient composition AlGaN layer 2c, the total amount of charges in the gradient composition AlGaN layer 2c is ±0. However, because the amounts of polarization at the upper end and the lower end are different from each other, insufficient charges are generated in the middle of the gradient composition AlGaN layer 2c. Therefore, as illustrated in FIG. 4C, positive fixed charges are three-dimensionally distributed in the gradient composition AlGaN layer 2c. A semiconductor in which positive fixed charges are three-dimensionally distributed in this way exhibits the properties of an n-type semiconductor (hereinafter, also referred to as “n-type semiconductor properties” or “n-type properties”) as with a semiconductor doped with n-type impurities.

With the semiconductor device 1A illustrated in FIG. 3, the channel layer 20 is made of a gradient composition AlGaN that exhibits the n-type semiconductor properties by increasing the Al composition toward one surface ((0001) plane) of the layer.

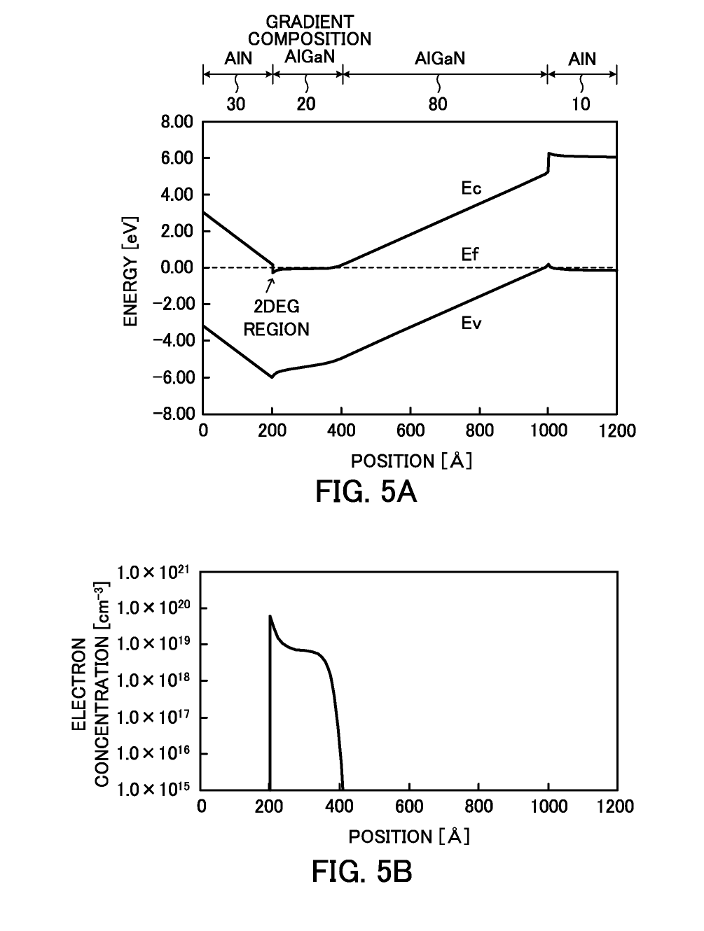

FIGS. 5A and 5B illustrate an energy band structure and an electron concentration distribution of the example of the semiconductor device according to the first embodiment. FIG. 5A illustrates an energy band structure of the example of the semiconductor device. In FIG. 5A, Ec represents a conduction band, Ev represents a valence band, and Ef represents a Fermi level. FIG. 5B illustrates an electron concentration distribution of the example of the semiconductor device.

The energy band structure of the semiconductor device 1A in which AlN is used for the substrate 10, AlGaN is used for the buffer layer 80, a gradient composition AlGaN is used for the channel layer 20, and AlN is used for the barrier layer 30 is illustrated in FIG. 5A. Because the conduction band Ec of the gradient composition AlGaN of the channel layer 20 is on the lower energy side than the Fermi level Ef, a 2DEG region is generated in the channel layer 20 near the barrier layer 30.

In the semiconductor device 1A, as described above, the gradient composition AlGaN of the channel layer 20 has a structure in which the Al composition increases in the direction from the buffer layer 80 or the substrate 10 toward the barrier layer 30. As a result, the n-type semiconductor properties are exhibited. Because the channel layer 20 is made of a gradient composition AlGaN having the n-type semiconductor properties, the internal electric field of the channel layer 20 is reduced. That is to say, as illustrated in FIG. 5A, the conduction band Ec of the gradient composition AlGaN of the channel layer 20 is pushed down to a low energy side, compared with a case where Al of AlGaN is not gradient. As a result, in the semiconductor device 1A, as illustrated in FIG. 5B, an electron concentration distribution in which electrons spread toward the buffer layer 80 in the channel layer 20 is obtained. Therefore, in the semiconductor device 1A, electron concentration in the channel layer 20 is increased, the total number of electrons is increased, and electron mobility is increased.

By increasing electron concentration and electron mobility in the channel layer 20, the output characteristics of the semiconductor device 1A are improved. By using the above-described gradient composition AlGaN for the channel layer 20, a high-performance semiconductor device 1A having high electron concentration and high electron mobility in the channel layer 20 and having excellent output characteristics is realized.

The gradient composition AlGaN of the channel layer 20 will be further described.

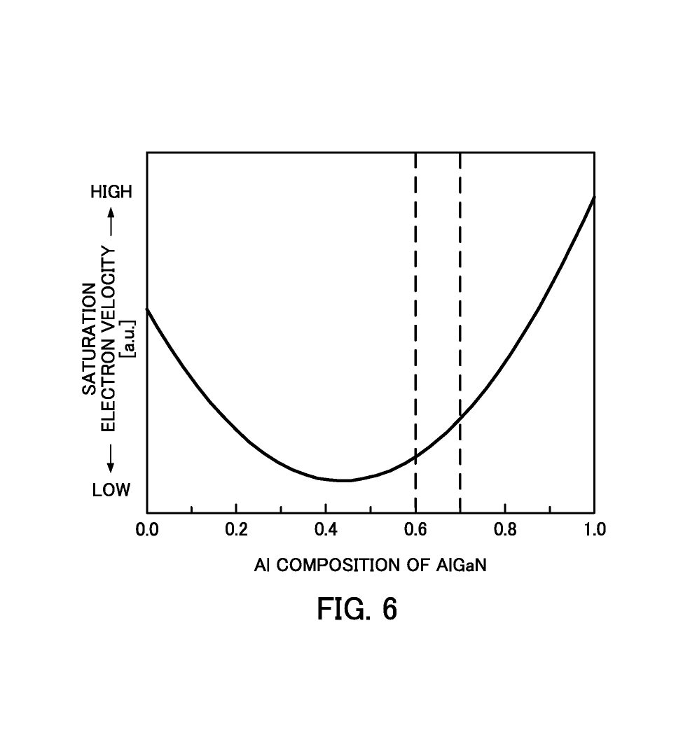

FIG. 6 illustrates an example of the characteristics of AlGaN. FIG. 6 schematically illustrates the relationship between the Al composition of AlGaN and saturation electron velocity.

The saturation electron velocity of AlGaN may vary according to the Al composition. For example, as illustrated in FIG. 6, the saturation electron velocity of AlGaN tends to be minimum when the Al composition of AlGaN is around 0.5.

Therefore, in the semiconductor device 1A, in order to improve electron concentration and electron mobility in the channel layer 20 near the barrier layer 30, the Al composition at the surface 20a of the gradient composition AlGaN of the channel layer 20, at the side where the barrier layer 30 is located, is set to be 0.5 or more, preferably 0.6 or more, and more preferably 0.7 or more.

However, in order to generate a 2DEG region in the channel layer 20, the Al composition at the surface 20a of the gradient composition AlGaN of the channel layer 20 is set to be lower than the Al composition at the surface 30b of an Al-containing nitride semiconductor of the barrier layer 30 at a side where the channel layer 20 is located. For example, the Al composition at the surface 20a of the channel layer 20 is set to be lower than the Al composition at the surface 30b of the barrier layer 30 by 0.1 or more. As a result, a HEMT capable of generating a 2DEG region in which a constant electron concentration and electron mobility are obtained in the channel layer 20 is realized.

In the semiconductor device 1A, the Al composition of the gradient composition AlGaN of the channel layer 20 is set so as to enable high saturation electron velocity in the channel layer 20, generation of a 2DEG region, gradient Al composition with a predetermined change amount, exhibition of the n-type semiconductor properties, lattice matching with the substrate 10 and the like, and the like. For example, the Al composition of the gradient composition AlGaN of the channel layer 20 is set so that the difference between the average Al composition and the Al composition of AlN of the substrate 10 is 0.5 or less.

### Second Embodiment

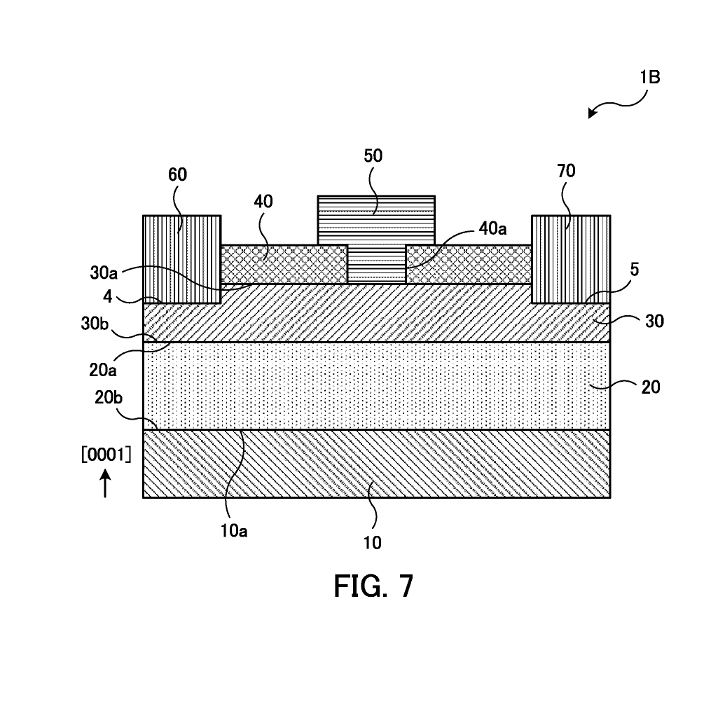

FIG. 7 illustrates an example of a semiconductor device according to a second embodiment. FIG. 7 is a fragmentary schematic sectional view of an example of a semiconductor device.

A semiconductor device 1B illustrated in FIG. 7 is an example of a HEMT using a nitride semiconductor. The semiconductor device 1B includes a substrate 10, a channel layer 20, a barrier layer 30, a passivation film 40, a gate electrode 50, a source electrode 60, and a drain electrode 70. In the semiconductor device 1B, a 2DEG region is generated in the channel layer 20 near the barrier layer 30.

The semiconductor device 1B is different from the semiconductor device 1A described in the first embodiment in that a buffer layer 80 is not formed between the substrate 10 and the channel layer 20. The other structure of the semiconductor device 1B may be the same as that of the semiconductor device 1A. The substrate 10, the channel layer 20, the barrier layer 30, the passivation film 40, the gate electrode 50, the source electrode 60, and the drain electrode 70 of the semiconductor device 1B may be the same as those described for the semiconductor device 1A.

In the semiconductor device 1B, the channel layer 20 is formed at a side of the substrate 10 containing AlN where the surface 10a is located. The channel layer 20 is made of a gradient composition AlGaN in which the Al composition increases in a direction from the substrate 10 toward the barrier layer 30. The barrier layer 30 using an Al-containing nitride semiconductor is formed at a side of the channel layer 20 where the surface 20a is located. The channel layer 20 and the barrier layer 30 are formed to be lattice-matched with the substrate 10.

For example, AlGaN in which the difference between the average Al composition and the Al composition of AlN of the substrate 10 is 0.5 or less is used as the gradient composition AlGaN of the channel layer 20.

For example, the Al composition at a surface 20b of the gradient composition AlGaN of the channel layer 20, at a side where the substrate 10 is located, is preferably set to 0.3 or more, and more preferably 0.5 or more in order to improve the breakdown voltage of the semiconductor device 1B. The Al composition at the surface 20a of the gradient composition AlGaN of the channel layer 20, at a side where the barrier layer 30 is located, is preferably set to 0.6 or more, and more preferably 0.7 or more in order to improve electron mobility in the channel layer 20 near the barrier layer 30 in the semiconductor device 1B.

For example, the amount of a change in the Al composition of the gradient composition AlGaN of the channel layer 20 that increases in the direction from the substrate 10 toward the barrier layer 30 is preferably set to 0.0002 nm⁻¹ or more, and more preferably 0.001 nm⁻¹ or more. The Al composition of the gradient composition AlGaN of the channel layer 20 may increase continuously or stepwise in the direction from the substrate 10 toward the barrier layer 30.

In the semiconductor device 1B, the channel layer 20 using a gradient composition AlGaN is formed on the substrate 10 containing AlN. As a result, the influence of polarization of AlN of the substrate 10 on the internal electric field of the channel layer 20 may be larger than that in a case where AlGaN is interposed as a buffer layer 80 between the substrate 10 and the channel layer 20. Therefore, in the semiconductor device 1B, the structure of the gradient composition AlGaN may be properly set so that a reduction in the internal electric field, the spread of an electron concentration distribution, and the improvement of electron mobility are realized by the n-type semiconductor properties exhibited in the gradient composition AlGaN of the channel layer 20. For example, the average Al composition of the gradient composition AlGaN of the channel layer 20, the amount of a change in or the gradient form of the Al composition increasing in the direction from the substrate 10 toward the barrier layer 30, the thickness in the c-axis direction, and the like may be properly set.

The barrier layer 30 using an Al-containing nitride semiconductor is formed at the side of the channel layer 20 using a gradient composition AlGaN where the surface 20a is located. In order to generate a 2DEG region in which a constant electron concentration and electron mobility are obtained in the channel layer 20, the Al composition at the surface 20a of the channel layer 20 is set to be lower than the Al composition at the surface 30b of the barrier layer 30, for example, lower by 0.1 or more.

The gate electrode 50, the source electrode 60, the drain electrode 70, and the passivation film 40 are provided at a side of the barrier layer 30 where the surface 30a is located. A predetermined voltage is applied to each of the source electrode 60, the drain electrode 70, and the gate electrode 50, and the operation of the semiconductor device 1B as a transistor is realized.

With the semiconductor device 1B having the structure described above, because the channel layer 20 is made of a gradient composition AlGaN that exhibits the n-type semiconductor properties, the internal electric field of the channel layer 20 is reduced and an electron concentration distribution in the channel layer 20 spreads toward the substrate 10. This is the same with the semiconductor device 1A. Therefore, electron concentration in the channel layer 20 is increased, the total number of electrons is increased, and electron mobility is increased.

By increasing electron concentration and electron mobility in the channel layer 20, the output characteristics of the semiconductor device 1B are enhanced. By using the above-described gradient composition AlGaN for the channel layer 20, a high-performance semiconductor device 1B having a high electron concentration and a high electron mobility in the channel layer 20 and having excellent output characteristics is realized.

### Third Embodiment

An example of a method for manufacturing a semiconductor device will be described as a third embodiment. A method for manufacturing the semiconductor device 1A (FIG. 3) described in the first embodiment is taken as an example.

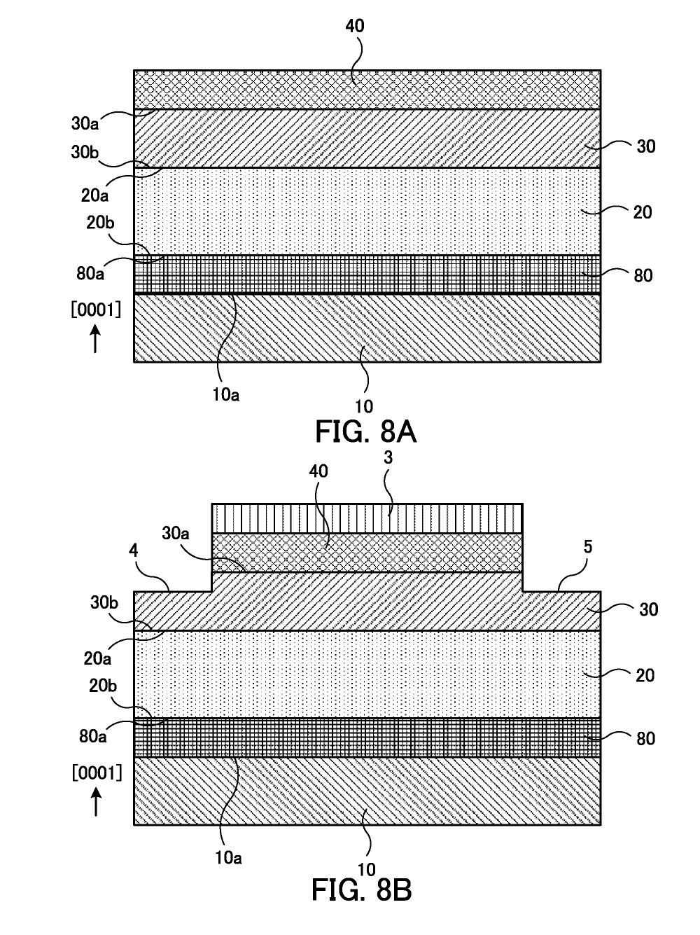

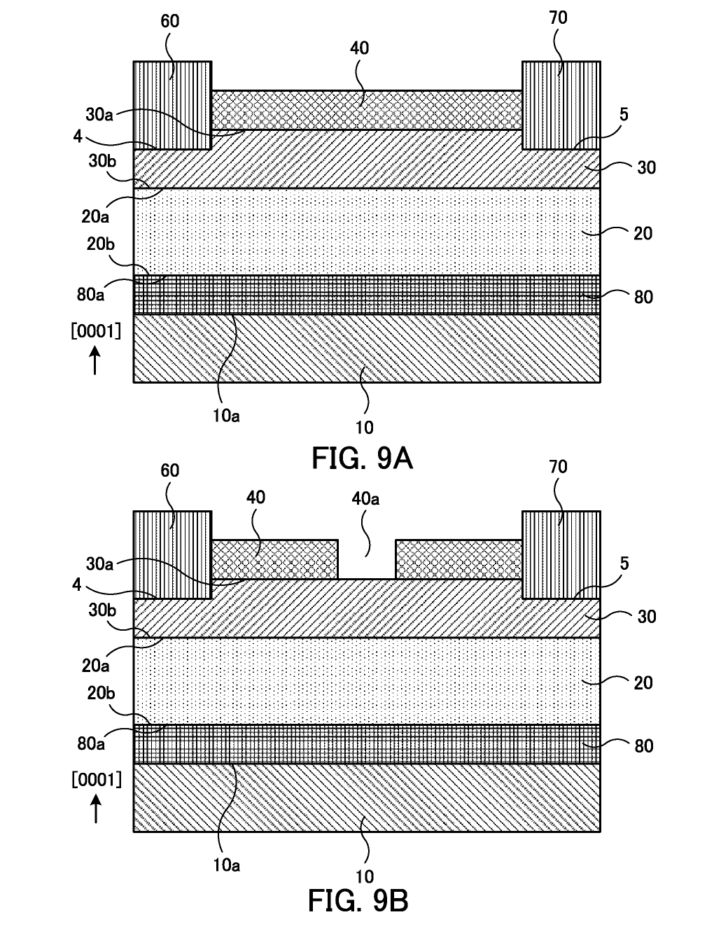

FIGS. 8A and 8B and FIGS. 9A and 9B are views for describing an example of a method for manufacturing the semiconductor device according to a third embodiment. FIG. 8A is a fragmentary schematic sectional view of an example of a semiconductor growth and passivation film formation step. FIG. 8B is a fragmentary schematic sectional view of an example of a recess formation step. FIG. 9A is a fragmentary schematic sectional view of an example of a source electrode and drain electrode formation step. FIG. 9B is a fragmentary schematic sectional view of an example of an opening formation step.

First, as illustrated in FIG. 8A, a buffer layer 80, a channel layer 20, and a barrier layer 30 are grown in order on a substrate 10 using the MOVPE method. For example, an AlN substrate is used as the substrate 10. For example, Alₓ₁Ga₁₋ₓ₁N (0.3 ≤ x1 ≤ 1.0) having a thickness of 800 nm is grown as the buffer layer 80 at a side of the substrate 10 where a surface 10a of the substrate 10 is located. At a side of the buffer layer 80 where a surface 80a of the buffer layer 80 is located, for example, a gradient composition AlₐGa₁₋ₐN (0.3 ≤ a < 1.0) having a thickness of 200 nm in which the Al composition increases in a direction from the buffer layer 80 toward the barrier layer 30 is grown, as the channel layer 20. For example, In_{y2}Alₓ₂Ga_{1-x2-y2}N (0.3 ≤ x2 ≤ 1.0, 0 ≤ y2 ≤ 0.2) having a thickness of 20 nm is grown as the barrier layer 30 at a side of the channel layer 20 where a surface 20a of the channel layer 20 is located.

The gradient composition AlₐGa₁₋ₐN of the channel layer 20 is grown so that the Al composition (a1) at a side of the buffer layer 80 is low and the Al composition (a2) at a side of the barrier layer 30 is high (a1<a2). The Al composition a of the channel layer 20 may increase monotonously or stepwise in the direction from the buffer layer 80 toward the barrier layer 30. The amount of a change in the Al composition a of the channel layer 20 is set to, for example, preferably 0.0002 nm⁻¹ or more, and more preferably 0.001 nm⁻¹ or more. In order to improve the breakdown voltage, the Al composition (a1) at the side of the buffer layer 80 is preferably set to 0.3 or more, and more preferably 0.5 or more. In order to improve electron mobility near the barrier layer 30, the Al composition (a2) at the side of the barrier layer 30 is preferably set to 0.6 or more, and more preferably 0.7 or more.

In the growth of a nitride semiconductor using the MOVPE method, for the growth of AlN, mixed gas of tri-methyl-aluminum (TMAl) as an Al source and ammonia (NH₃) is used. For the growth of AlGaN, mixed gas of TMAl as an Al source, tri-methyl-gallium (TMGa) as a gallium (Ga) source, and NH₃ is used. Furthermore, for the growth of InAlGaN, mixed gas of tri-methyl-indium (TMIn) as an In source, TMAl as an Al source, TMGa as a Ga source, and NH₃ is used. For the growth of InAlN, mixed gas of TMIn as an In source, TMAl as an Al source, and NH₃ is used. The supply and stop (switching) of raw materials such as TMAl, TMGa, and TMIn and a flow rate at the time of supply (mixing ratio with other raw materials) are properly set according to nitride semiconductors to be grown. Hydrogen or nitrogen is used as carrier gas.

After the growth of the buffer layer 80, the channel layer 20, and the barrier layer 30 using the MOVPE method, as illustrated in FIG. 8A, the passivation film 40 is formed at a side of the barrier layer 30 where a surface 30a of the barrier layer 30 is located. For example, the passivation film 40 having a thickness in the range of 2 nm to 500 nm, for example, a thickness of 100 nm is formed using a plasma chemical vapor deposition (CVD) method. The passivation film 40 may be formed using an atomic layer deposition (ALD) method, a sputtering method, or the like in place of the plasma CVD method. For example, an oxide, a nitride, or an oxynitride containing at least one of Si, Al, Hf, Zr, Ti, Ta, and W is used for the passivation film 40. For example, SiN is formed as the passivation film 40.

After the passivation film 40 is formed, an element isolation region (not illustrated) is formed. For example, a resist pattern (not illustrated) having an opening in a region where the element isolation region is to be formed is formed by photolithography. Then, using the formed resist pattern as a mask, dry etching using chlorine (Cl)-based gas or ion implantation of argon (Ar) or the like is performed on a nitride semiconductor layer in the opening. As a result, the element isolation region is formed. After the element isolation region is formed, the resist pattern used as the mask is removed using an organic solvent or the like.

Next, as illustrated in FIG. 8B, a surface protective film 3 is formed on the passivation film 40. For example, the surface protective film 3 is formed using the plasma CVD method. The surface protective film 3 may be formed by the ALD method, the sputtering method, or the like. For the surface protective film 3, for example, an oxide, a nitride, or an oxynitride containing at least one of Si, Al, Hf, Zr, Ti, Ta, and W is used. For example, silicon oxide (SiO₂) is formed as the surface protective film 3.

After the surface protective film 3 is formed, as illustrated in FIG. 8B, recesses 4 and 5 are formed in the barrier layer 30 in regions where the source electrode 60 and the drain electrode 70 are to be formed. For example, a resist pattern (not illustrated) having openings in regions where the source electrode 60 and the drain electrode 70 are to be formed is formed by the photolithography. Then, using the formed resist pattern as a mask, dry etching using fluorine (F)-based gas is performed on the surface protective film 3 and the passivation film 40 in the openings. Furthermore, dry etching using Cl-based gas is performed on the barrier layer 30 exposed by the dry etching of the passivation film 40. As a result, the recesses 4 and 5 are formed in a part of the barrier layer 30. After the recesses 4 and 5 are formed, the resist pattern used as the mask is removed using an organic solvent or the like.

Next, as illustrated in FIG. 9A, the source electrode 60 is formed in one recess 4 of the barrier layer 30 and the drain electrode 70 is formed in the other recess 5 of the barrier layer 30. For example, a resist pattern (not illustrated) having openings in regions of the recess 4 and the recess 5 of the barrier layer 30 is formed by the photolithography. Next, a metal is deposited on the resist pattern and in the openings by a vacuum deposition method. As an example, Ta having a thickness of 20 nm is deposited and Al having a thickness of 200 nm is deposited thereon. After the metal is deposited, the resist pattern is removed together with the metal deposited thereon by a lift-off technique. As a result, the source electrode 60 and the drain electrode 70 are formed in the recesses 4 and 5, respectively, of the barrier layer 30. After that, heat treatment (alloying treatment) is performed in a nitrogen atmosphere in the range of 400 to 1000°C, for example, at 550°C, and ohmic characteristics of the source electrode 60 and the drain electrode 70 are established. By doing so, the source electrode 60 and the drain electrode 70 functioning as an ohmic electrode are formed.

After the source electrode 60 and the drain electrode 70 are formed, the surface protective film 3 is removed. As a result, the state illustrated in FIG. 9A is obtained.

Next, as illustrated in FIG. 9B, the passivation film 40 in a region where the gate electrode 50 is to be formed is partially removed, and an opening 40a leading to the barrier layer 30 is formed. For example, a resist pattern (not illustrated) having an opening in a region where the gate electrode 50 is to be formed is formed by the photolithography. Then, using the formed resist pattern as a mask, dry etching using F-based gas is performed on the passivation film 40 in the opening. In addition, etching of the passivation film 40 may be performed by wet etching using hydrofluoric acid, buffered hydrofluoric acid, or the like. An opening 40a is formed in a part of the passivation film 40 by predetermined etching. After the opening 40a is formed, the resist pattern used as the mask is removed using an organic solvent or the like.

After the opening 40a of the passivation film 40 is formed, the gate electrode 50 is formed in the opening 40a as illustrated in FIG. 3. For example, a resist pattern (not illustrated) having an opening in a region where the gate electrode 50 is to be formed is formed by the photolithography. Next, a metal is deposited on the resist pattern and in the opening by the vacuum deposition method. As an example, Ni having a thickness of 30 nm is deposited and Au having a thickness of 400 nm is deposited thereon. After the metal is deposited, the resist pattern is removed together with the metal deposited thereon by the lift-off technique. As a result, the gate electrode 50 functioning as a Schottky electrode is formed in the opening 40a of the passivation film 40. For example, as illustrated in FIG. 3, the gate electrode 50 is formed not only in the opening 40a but also on a part of the upper surface of the passivation film 40 outside the opening 40a.

Through the steps described above, the semiconductor device 1A having the structure illustrated in FIG. 3 is manufactured.

In the semiconductor device 1A, the channel layer 20 using a gradient composition AlGaN, in which the Al composition increases in a direction from the buffer layer 80 or the substrate 10 toward the barrier layer 30, is formed. As a result, the channel layer 20 exhibits the n-type semiconductor properties, the internal electric field of the channel layer 20 is reduced, and an electron concentration distribution in the channel layer 20 spreads toward the buffer layer 80 or the substrate 10. Therefore, a high-performance semiconductor device 1A having excellent output characteristics in which electron concentration and electron mobility in the channel layer 20 are increased is realized.

The type of a metal and the layer structure used for the gate electrode 50, the source electrode 60, and the drain electrode 70 of the semiconductor device 1A are not limited to the example described above, and a method for forming them is also not limited to the example described above. For each of the gate electrode 50, the source electrode 60, and the drain electrode 70, a single-layer metal may be used or a metal having a laminated structure may be used. When the source electrode 60 and the drain electrode 70 are formed, the heat treatment described above is not always needed as long as ohmic characteristics are realized by forming (depositing) these metals. Furthermore, when the gate electrode 50 is formed, heat treatment may be further performed after the metal is formed.

An example in which an AlN substrate is used as the substrate 10 is illustrated, but a substrate 10 having a structure in which an AlN layer is laminated on various base substrates may be used as the substrate 10. The substrate 10 may be a semi-insulating substrate or a conductive substrate.

An example in which the gate electrode 50 functioning as a Schottky electrode is formed in the semiconductor device 1A has been described. However, a gate insulating film using an oxide, a nitride, an oxynitride, or the like may be formed between the gate electrode 50 and the barrier layer 30 to form an MIS type gate structure. Furthermore, a cap layer using a doped (for example, a p-type) or non-doped nitride semiconductor may be interposed between the gate electrode 50 and the barrier layer 30.

In the steps of FIGS. 8B and 9A, an example in which the source electrode 60 and the drain electrode 70 are formed in the recesses 4 and 5, respectively, formed in the barrier layer 30 is described. Alternatively, the source electrode 60 and the drain electrode 70 may be formed on the barrier layer 30 without forming the recesses 4 and 5. Alternatively, the recesses 4 and 5 may be formed so as to penetrate the barrier layer 30 and reach the inside of the channel layer 20, an n-type nitride semiconductor may be regrown therein as a contact layer, and the source electrode 60 and the drain electrode 70 may be formed thereon.

An example of a method for manufacturing the semiconductor device 1A as illustrated in FIG. 3 has been described. However, if the semiconductor device 1B illustrated in FIG. 7 is manufactured, then the growth of the buffer layer 80 may be omitted in the step of FIG. 8A. After that, according to the example described above, the surface protective film 3 and the recesses 4 and 5 are formed (FIG. 8B), the source electrode 60 and the drain electrode 70 are formed (FIG. 9A), the opening 40a of the passivation film 40 is formed (FIG. 9B), and the gate electrode 50 is further formed. By doing so, the semiconductor device 1B illustrated in FIG. 7 is manufactured.

The first, second, and third embodiments have been described.

The semiconductor devices 1A, 1B, and the like described above may be applied to various electronic devices. As examples, cases where the semiconductor devices 1A, 1B, and the like having the structure described above are applied to a semiconductor package, a power factor correction circuit, a power supply device, and an amplifier will now be described.

### Fourth Embodiment

An example in which the semiconductor devices 1A, 1B, and the like having the structure described above are applied to a semiconductor package will be described as a fourth embodiment.

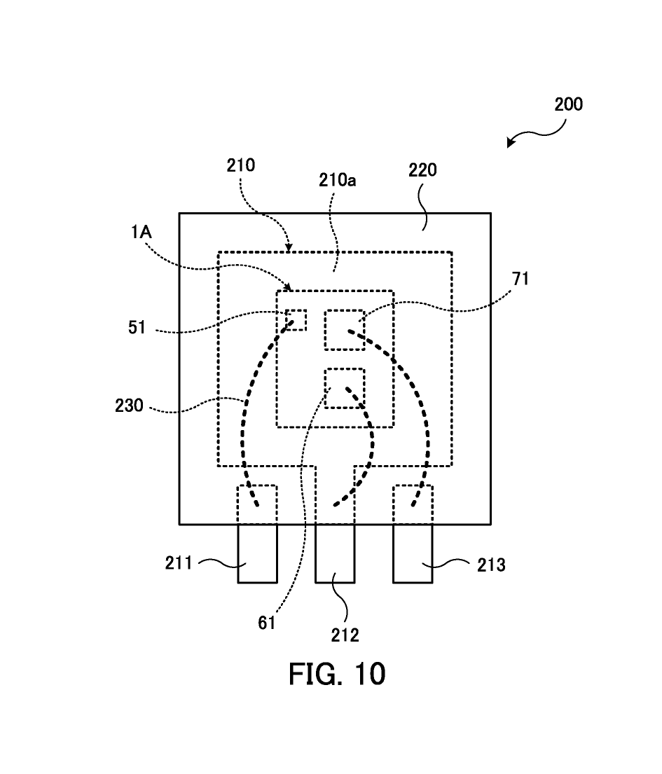

FIG. 10 illustrates an example of a semiconductor package according to a fourth embodiment. FIG. 10 is fragmentary schematic plan view of an example of a semiconductor package.

A semiconductor package 200 illustrated in FIG. 10 is an example of a discrete package. The semiconductor package 200 includes, for example, the semiconductor device 1A (FIG. 3) described in the first embodiment, a lead frame 210 on which the semiconductor device 1A is mounted, and resin 220 that seals them.

The semiconductor device 1A is mounted on, for example, a die pad 210a of a lead frame 210 using a die attach material or the like (not illustrated). The semiconductor device 1A includes a pad 51 connected to the gate electrode 50, a pad 61 connected to the source electrode 60, and a pad 71 connected to the drain electrode 70. The pad 51, the pad 61, and the pad 71 are connected to a gate lead 211, a source lead 212, and a drain lead 213, respectively, of the lead frame 210 using wires 230 made of Au, Al, or the like. The lead frame 210, the semiconductor device 1A mounted thereon, and the wire 230 connecting them are sealed with the resin 220 so that the gate lead 211, the source lead 212, and the drain lead 213 are partially exposed.

An external connection electrode connected to the source electrode 60 may be formed on a surface of the semiconductor device 1A opposite to a surface on which the pad 51 connected to the gate electrode 50 and the pad 71 connected to the drain electrode 70 are formed. The external connection electrode may be connected to the die pad 210a connected to the source lead 212 using a conductive bonding material such as solder.

For example, the semiconductor device 1A described in the first embodiment is used to obtain the semiconductor package 200.

As described above, in the semiconductor device 1A, the channel layer 20 using a gradient composition AlGaN in which the Al composition increases in the direction from the buffer layer 80 or the substrate 10 toward the barrier layer 30 is formed. As a result, the channel layer 20 exhibits the n-type semiconductor properties, the internal electric field of the channel layer 20 is reduced, and an electron concentration distribution in the channel layer 20 spreads toward the buffer layer 80 or the substrate 10. Therefore, a high-performance semiconductor device 1A having excellent output characteristics in which electron concentration and electron mobility in the channel layer 20 are increased is realized. By using this semiconductor device 1A, a high-performance semiconductor package 200 is realized.

The semiconductor device 1A is taken as an example, but the semiconductor package 200 is similarly obtained using another semiconductor device 1B or the like.

### Fifth Embodiment

An example in which the semiconductor devices 1A, 1B, and the like having the structure described above are applied to a power factor correction circuit will be described as a fifth embodiment.

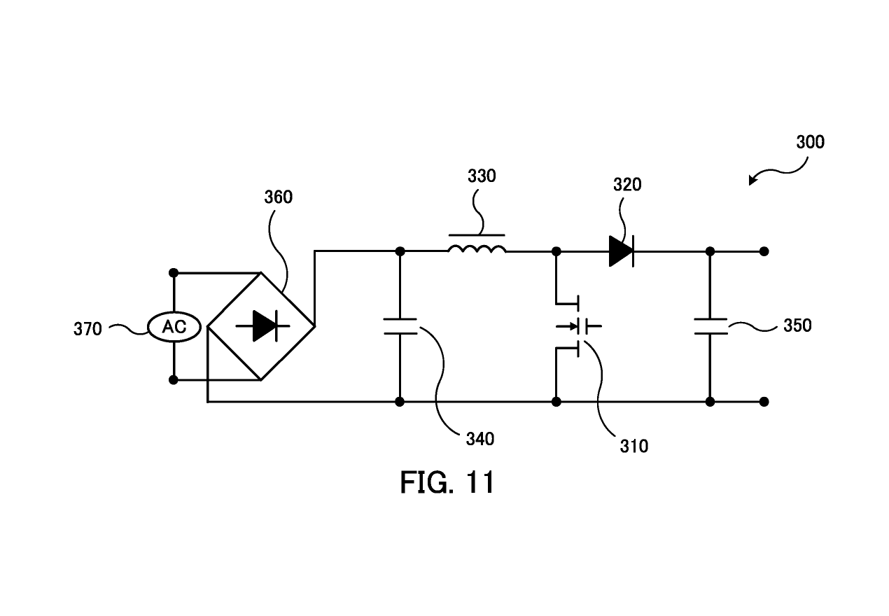

FIG. 11 illustrates an example of a power factor correction circuit according to a fifth embodiment. FIG. 11 is an equivalent circuit diagram of an example of a power factor correction circuit.

A power factor correction (PFC) circuit 300 illustrated in FIG. 11 includes a switching element 310, a diode 320, a choke coil 330, a capacitor 340, a capacitor 350, a diode bridge 360, and an AC power supply 370 (AC).

In the PFC circuit 300, a drain electrode of the switching element 310 is connected to an anode terminal of the diode 320 and one terminal of the choke coil 330. A source electrode of the switching element 310 is connected to one terminal of the capacitor 340 and one terminal of the capacitor 350. The other terminal of the capacitor 340 and the other terminal of the choke coil 330 are connected to each other. The other terminal of the capacitor 350 and a cathode terminal of the diode 320 are connected to each other. Furthermore, a gate driver is connected to a gate electrode of the switching element 310. The AC power supply 370 is connected between both terminals of the capacitor 340 via the diode bridge 360, and a DC power supply (DC) is taken out from between both terminals of the capacitor 350.

For example, the semiconductor devices 1A, 1B, and the like are used for the switching element 310 of the PFC circuit 300 having the structure described above.

As described above, in the semiconductor devices 1A, 1B, and the like, the channel layer 20 using a gradient composition AlGaN in which the Al composition increases in the direction from the buffer layer 80 or the substrate 10 toward the barrier layer 30 is formed. As a result, the channel layer 20 exhibits the n-type semiconductor properties, the internal electric field of the channel layer 20 is reduced, and an electron concentration distribution in the channel layer 20 spreads toward the buffer layer 80 or the substrate 10. Therefore, high-performance semiconductor devices 1A, 1B, and the like having excellent output characteristics in which electron concentration and electron mobility in the channel layer 20 are increased are realized. A high-performance PFC circuit 300 is realized by using these semiconductor devices 1A, 1B, and the like.

### Sixth Embodiment

An example in which the semiconductor devices 1A, 1B, and the like having the structure described above are applied to a power supply device will be described as a sixth embodiment.

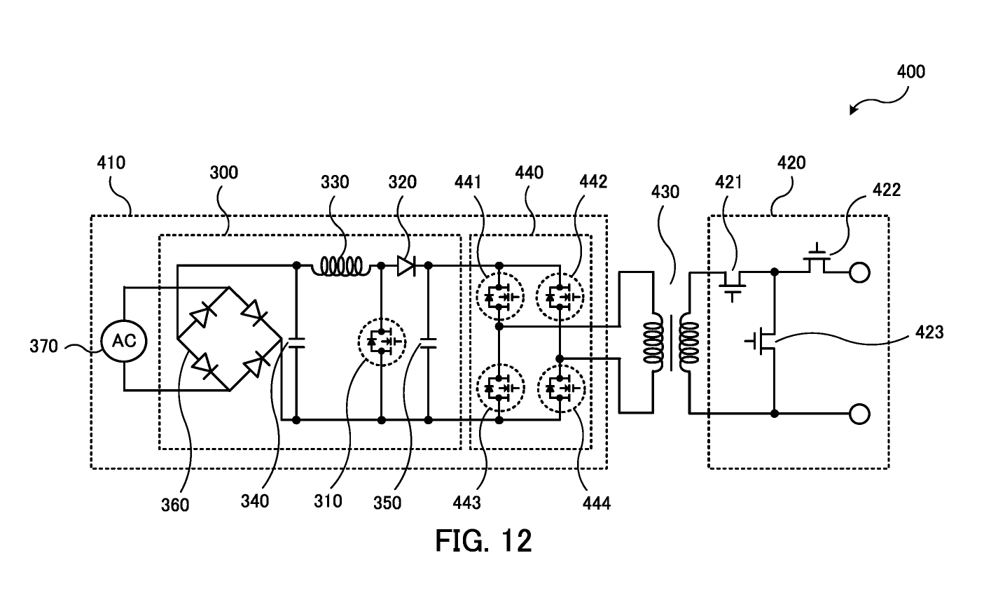

FIG. 12 illustrates an example of a power supply device according to a sixth embodiment. FIG. 12 is an equivalent circuit diagram of an example of a power supply device.

A power supply device 400 illustrated in FIG. 12 includes a primary-side circuit 410, a secondary-side circuit 420, and a transformer 430 located between the primary-side circuit 410 and the secondary-side circuit 420.

The primary-side circuit 410 includes the PFC circuit 300 described in the fifth embodiment and an inverter circuit, for example, a full-bridge inverter circuit 440 connected between both terminals of the capacitor 350 of the PFC circuit 300. The full-bridge inverter circuit 440 includes a plurality of, for example, four switching elements 441, 442, 443, and 444.

The secondary-side circuit 420 includes a plurality of, for example, three switching elements 421, 422, and 423.

For example, the semiconductor devices 1A, 1B, and the like are used for the switching element 310 of the PFC circuit 300 and the switching elements 441 to 444 of the full-bridge inverter circuit 440 included in the primary-side circuit 410 of the power supply device 400 having the structure described above. For example, MIS FETs using Si are used for the switching elements 421 to 423 of the secondary-side circuit 420 of the power supply device 400.

As described above, in the semiconductor devices 1A, 1B, and the like, the channel layer 20 using a gradient composition AlGaN in which the Al composition increases in a direction from the buffer layer 80 or the substrate 10 toward the barrier layer 30 is formed. As a result, the channel layer 20 exhibits the n-type semiconductor properties, the internal electric field of the channel layer 20 is reduced, and an electron concentration distribution in the channel layer 20 spreads toward the buffer layer 80 or the substrate 10. Therefore, a high-performance semiconductor devices 1A, 1B, and the like having excellent output characteristics in which electron concentration and electron mobility in the channel layer 20 are increased are realized. A high-performance power supply device 400 is realized by using the semiconductor devices 1A, 1B, and the like.

### Seventh Embodiment

An example in which the semiconductor devices 1A, 1B, and the like having the structure described above are applied to an amplifier will be described as a seventh embodiment.

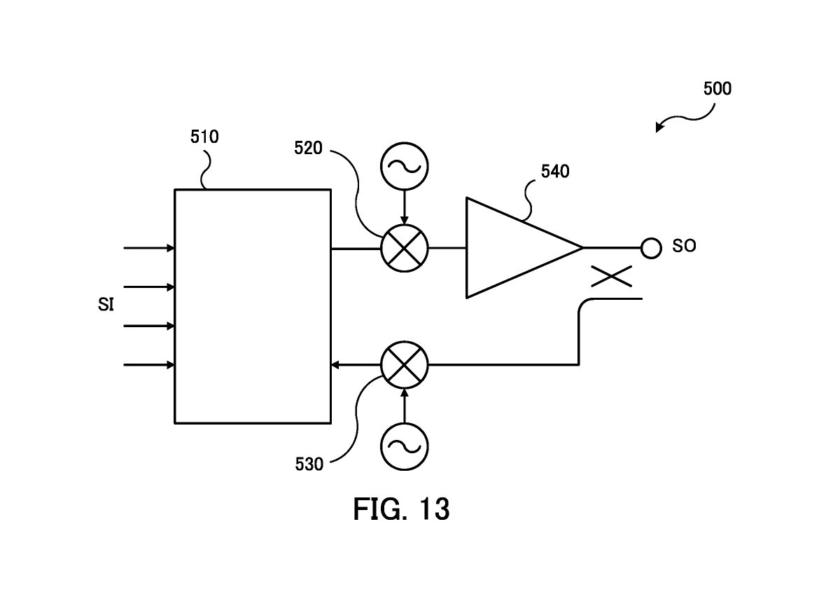

FIG. 13 illustrates an example of an amplifier according to a seventh embodiment. FIG. 13 is an equivalent circuit diagram of an example of an amplifier.

An amplifier 500 illustrated in FIG. 13 includes a digital predistortion circuit 510, a mixer 520, a mixer 530, and a power amplifier 540.

The digital predistortion circuit 510 compensates for nonlinear distortion of an input signal. The mixer 520 mixes an input signal SI whose nonlinear distortion has been compensated for with an AC signal. The power amplifier 540 amplifies a signal obtained by mixing the input signal SI with the AC signal. In the amplifier 500, for example, by switching a switch, an output signal SO is mixed with an AC signal by the mixer 530 and is sent to the digital predistortion circuit 510. The amplifier 500 may be used as a high-frequency amplifier or a high power amplifier.

The semiconductor devices 1A, 1B, and the like are used for the power amplifier 540 of the amplifier 500 having the structure described above.

As described above, in the semiconductor devices 1A, 1B, and the like, the channel layer 20 using a gradient composition AlGaN in which the Al composition increases in a direction from the buffer layer 80 or the substrate 10 toward the barrier layer 30 is formed. As a result, the channel layer 20 exhibits the n-type semiconductor properties, the internal electric field of the channel layer 20 is reduced, and an electron concentration distribution in the channel layer 20 spreads toward the buffer layer 80 or the substrate 10. Therefore, high-performance semiconductor devices 1A, 1B, and the like having excellent output characteristics in which electron concentration and electron mobility in the channel layer 20 are increased are realized. A high-performance amplifier 500 is realized by using the semiconductor devices 1A, 1B, and the like.

Various electronic devices (semiconductor package 200, the PFC circuit 300, the power supply device 400, the amplifier 500, described in the fourth to seventh embodiments respectively, and the like) to which the semiconductor devices 1A, 1B, and the like are applied may be mounted on various electronic apparatuses or electronic devices. For example, they may be mounted on various electronic apparatuses or electronic devices such as a computer (personal computer, a supercomputer, a server, or the like), a smartphone, a mobile phone, a tablet terminal, a sensor, a camera, an audio device, a measurement device, an inspection device, a manufacturing device, a transmitter, a receiver, and a radar device.

In one aspect, a high-performance semiconductor device is realized.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a substrate containing aluminum nitride (AlN);
a channel layer formed at a side of the substrate where a first surface of the substrate is located, the channel layer containing aluminum gallium nitride (AlGaN); and
a barrier layer formed at a side of the channel layer where a second surface of the channel layer opposite to the substrate is located,
wherein the channel layer and the barrier layer are lattice-matched to the substrate, and
the channel layer has an Al composition that increases in a direction from the substrate toward the barrier layer.

2. The semiconductor device according to claim 1, wherein a difference between an average Al composition of the channel layer and an Al composition of the substrate is 0.5 or less.

3. The semiconductor device according to claim 1, wherein an Al composition at the second surface of the channel layer is 0.6 or more.

4. The semiconductor device according to claim 1, wherein an amount of a change in the Al composition of the channel layer in the direction from the substrate toward the barrier layer is 0.0002 nm⁻¹ or more.

5. The semiconductor device according to claim 1, wherein the Al composition of the channel layer continuously increases in the direction from the substrate toward the barrier layer.

6. The semiconductor device according to claim 1, wherein the Al composition of the channel layer increases stepwise in the direction from the substrate toward the barrier layer.

7. The semiconductor device according to claim 1, further comprising a buffer layer formed between the substrate and the channel layer, the buffer layer containing AlGaN,
wherein the buffer layer is lattice-matched to the substrate.

8. The semiconductor device according to claim 7, wherein an average Al composition of the channel layer is higher than an average Al composition of the buffer layer.

9. The semiconductor device according to claim 1, wherein the barrier layer includes a nitride semiconductor containing Al, and
an Al composition at the second surface of the channel layer is lower than an Al composition at a third surface of the barrier layer facing toward the channel layer.

10. The semiconductor device according to claim 9, wherein the Al composition at the second surface of the channel layer is lower than the Al composition at the third surface of the barrier layer by 0.1 or more.

11. The semiconductor device according to claim 1, further comprising:
a source electrode and a drain electrode formed at a side of the barrier layer where a fourth surface of the barrier layer opposite to the channel layer is located, the source electrode and the drain electrode being spaced apart from each other; and
a gate electrode formed at the side of the barrier layer where the fourth surface is located, the gate electrode being formed between the source electrode and the drain electrode and spaced from each of the source electrode and the drain electrode.

12. The semiconductor device according to claim 1, wherein the substrate is an AlN substrate.

13. The semiconductor device according to claim 1, wherein the channel layer has a dislocation density of 1 × 10⁸ cm⁻² or less.

14. The semiconductor device according to claim 1, wherein the channel layer has a carbon concentration of 1 × 10¹⁹ cm⁻³ or less.

15. The semiconductor device according to claim 1, wherein the channel layer has an oxygen concentration of 1 × 10¹⁹ cm⁻³ or less.

16. A method of manufacturing a semiconductor device, the method comprising:
forming a channel layer at a side of a substrate where a first surface of the substrate is located, the channel layer containing AlGaN, the substrate containing AlN; and
forming a barrier layer at a side of the channel layer where a second surface of the channel layer opposite to the substrate is located;
wherein the forming of the channel layer and the forming of the barrier layer include forming the channel layer and the barrier layer such that the channel layer and the barrier layer are lattice-matched to the substrate, and
the forming of the channel layer includes forming the channel layer such that an Al composition of the channel layer increases in a direction from the substrate toward the barrier layer.

17. An electronic device comprising:
a semiconductor device including:
a substrate containing AlN;
a channel layer formed at a side of the substrate where a first surface of the substrate is located, the channel layer containing AlGaN; and
a barrier layer formed at a side of the channel layer where a second surface of the channel layer opposite to the substrate is located;
wherein the channel layer and the barrier layer are lattice-matched to the substrate, and
the channel layer has an Al composition that increases in a direction from the substrate toward the barrier layer.
